(19) United States
(12) Patent Application Publication
(10) Pub. No.: US 2023/0039078 A1
(43) Pub. Date: Feb. 9, 2023

(54) Combined dual-conductive key switch

(71) Applicants: Dongguan City Kaihua Electronics Co., Ltd, Dongguan (CN); MECHANICAL MEYBOARDS, LLC, Chandler, AZ (US)

(72) Inventors: Joel Tubre, Phoenix, AZ (US); FuXi Wu, Dongguan (CN)

(73) Assignee: MECHANICAL MEYBOARDS, LLC, Chandler, AZ (US)

(21) Appl. No.: 17/397,930

(22) Filed: Aug. 9, 2021

(51) Int. Cl. H01H 13/20; H01H 13/14; G01D 5/34

(52) U.S. Cl. CPC H01H 13/20; H01H 13/14; G01D 5/34

(57) ABSTRACT

A combined dual-conductive key switch including a base, a cover arranged above the base and a conductive core, wherein the combined dual-conductive key switch further includes a mechanical-conducting component and a light-conducting component which are electrically connected to a PCB respectively, wherein a conduction trigger block corresponding to the mechanical-conducting component and a light-blocking protrusion corresponding to the mechanical-conducting component are respectively arranged on the conductive core; and the conduction trigger block triggers a conduction stroke of conducting the mechanical-conducting component, which is different from the conduction stroke of conducting the light-conducting component triggered by the light-blocking protrusion. The combined dual-conductive key switch is provided for achieving dual-conductive functions of pressing once and performing two actions for a product.

### TECHNICAL FIELD

The utility model relates to a key switch, in particular to a combined dual-conductive key switch.

### BACKGROUND ART

At present, when a key switch on the market is pressed once, the key switch is only conductive once, that is, the key switch only has a single conduction function. Along with the wide application of the key switch, not only the key switch is continuously improved for its performance requirement, but also the function requirement to the key switch is higher and higher.

For example, it is required that the key switch can be conductive twice when the key switch is pressed once. When it is applied to games, the key switch with the function of being pressed once and conductive twice has higher speed and provides better user experience for players compared with the traditional key switch.

However, the key switches with the function of being pressed once and conductive twice have not been available on the market today.

### SUMMARY OF THE UTILITY MODEL

For the defects above, the purpose of the utility model is to provide a combined dual-conductive key switch for achieving dual-conductive functions of pressing once and performing two actions for a product, which gives more functions to the key switch and provides better user experience.

The technical solution adopted by the utility model for achieving the above purpose is as follows.

A combined dual-conductive key switch comprises a base, a cover arranged above the base and a conductive core, wherein it further comprises a mechanical-conducting component and a light-conducting component which are electrically connected to a PCB respectively, wherein a conduction trigger block corresponding to the mechanical-conducting component and a light-blocking protrusion corresponding to the mechanical-conducting component are respectively arranged on the conductive core; and the conduction trigger block triggers a conduction stroke of conducting the mechanical-conducting component, which is different from the conduction stroke of conducting the light-conducting component triggered by the light-blocking protrusion.

As a further improvement of the utility model, the height of the outer edge of the conduction trigger block close to the mechanical-conducting component is not equal to the distance between the light-blocking protrusion and the light-conducting component.

As a further improvement of the utility model, the height of the outer edge of the conduction trigger block close to the mechanical-conducting component is less than the distance between the light-blocking protrusion and the light-conducting component.

As a further improvement of the utility model, the height of the outer edge of the conduction trigger block close to the mechanical-conducting component is greater than the distance between the light-blocking protrusion and the light-conducting component.

As a further improvement of the utility model, an inclined surface is formed on an upper part of a side edge of the conduction trigger block.

As a further improvement of the utility model, the mechanical-conducting component comprises a stationary plate and a movable plate, a stationary contact is provided on the stationary plate, a movable contact corresponding to the stationary contact is provided on the movable plate, and at least one contact protrusion corresponding to the conduction trigger block is formed on the movable plate.

As a further improvement of the present utility model, the light-conducting component comprises a light emission element and a light reception element.

As a further improvement of the utility model, an abdicating opening for the light-blocking protrusion to move up and down is formed on the base.

The utility model has the following beneficial effects. In a single key switch, the mechanical-conducting component and the light-conducting component are additionally arranged. When the conduction stroke of conducting the mechanical-conducting component triggered by the conduction trigger block is set, and is different from the conduction stroke of conducting the light-conducting component triggered by the light-blocking protrusion, two groups of conduction components are triggered to conduct in sequence by pressing the conductive core downwards, thereby achieving dual-conductive functions of pressing once and performing two actions for a product, which gives more functions to the key switch and provides better user experience.

The above mentioned is an overview of the technical scheme of the utility model. The following is a further explanation of the utility model in combination with the attached drawings and specific implementations.

### BRIEF DESCRIPTION OF THE DRAWINGS

FIG. 1 is an exploded view of the utility model;

FIG. 2 is a schematic view of the external structure of the utility model;

FIG. 3 is a sectional view of the utility model;

FIG. 4 is a schematic view of the structure of a conductive core in the utility model;

FIG. 5 is a schematic view of the structure in which a height d1 of an outer edge of a conduction trigger block close to a mechanical-conducting component in the utility model is less than a distance d2 between a light-blocking protrusion and a light-conducting component;

FIG. 6 is a schematic view showing the structure in which the mechanical-conducting component is conducted earlier when the height d1 of the outer edge of the conduction trigger block close to the mechanical-conducting component is less than the distance d2 between the light-blocking protrusion and the light-conducting component in the utility model;

FIG. 7 is a schematic view showing the structure in which the height d1 of the outer edge of the conduction trigger block close to the mechanical-conducting component is greater than the distance d2 between the light-blocking protrusion and the light-conducting component in the utility model;

FIG. 8 is a schematic view showing the structure in which the light-conducting component is conducted earlier when the height d1 of the outer edge of the conduction trigger block close to the mechanical-conducting component is greater than the distance d2 between the light-blocking protrusion and the light-conducting component in the utility model;

FIG. 9 is a schematic structural view of a mechanical-conducting component in the utility model;

FIG. 10 is a schematic view of a part of the structure of the utility model;

FIG. 11 is a schematic view of another part of the structure of the utility model;

FIG. 12 is a schematic view of the structure of a base in the utility model.

### DETAILED DESCRIPTION

In order to further explain the technical means and effects of the present utility model for achieving the intended purpose, the following detailed description of the embodiments of the present utility model will be made with reference to the accompanying drawings and preferred embodiments.

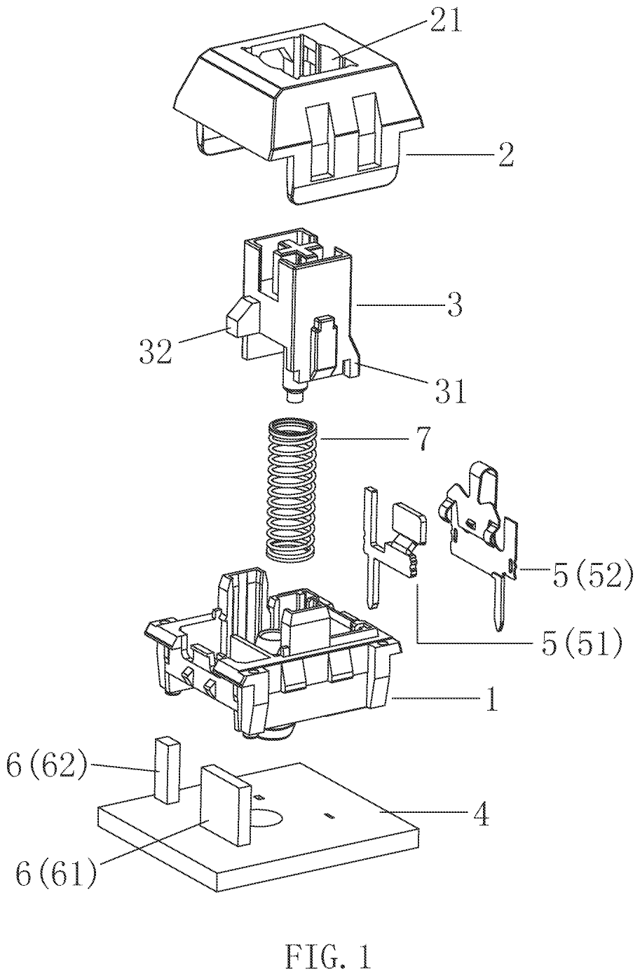

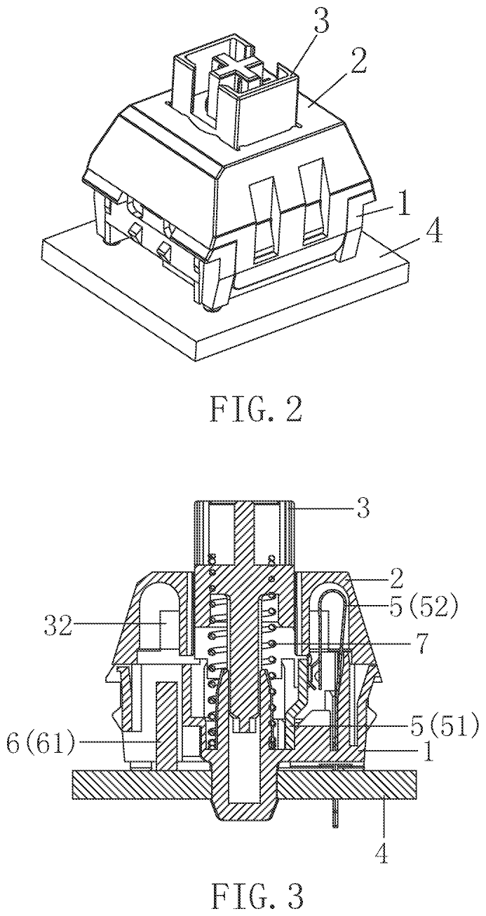

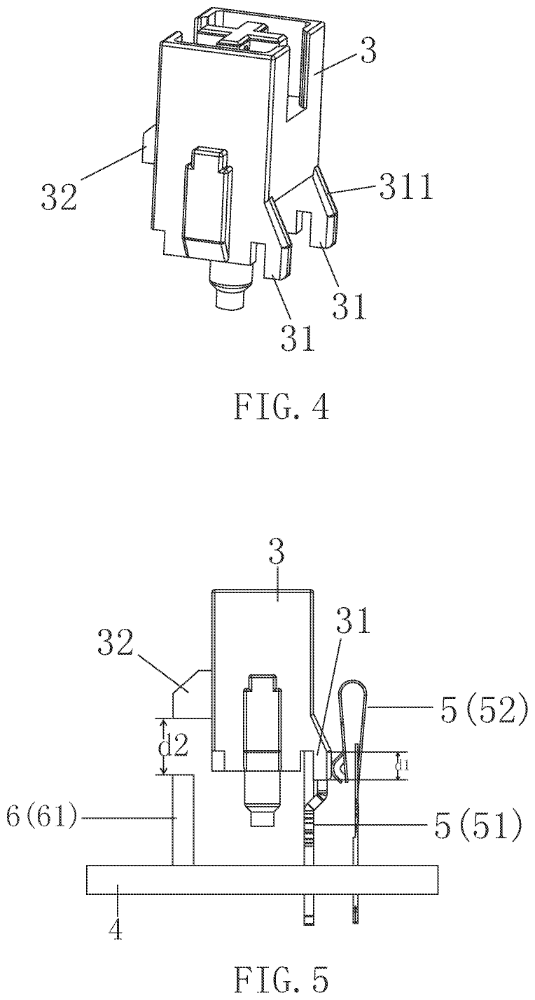

Referring to FIGS. 1 to 4, the embodiment provides a combined dual-conductive key switch comprising a base 1, a cover 2 arranged above the base 1, and a conductive core 3, wherein an opening 21 for allowing an upper part of the conductive core 3 to pass through is formed in the cover 2 so as to press the conductive core 3 downwards to trigger the conduction of the key switch. The combined dual-conductive key switch of the embodiment further comprises a mechanical-conducting component 5 and a light-conducting component 6 which are electrically connected to the PCB 4 respectively, wherein a conduction trigger block 31 corresponding to the mechanical-conducting component 5 and a light-blocking protrusion 32 corresponding to the light-conducting component 6 are respectively arranged on the conductive core 3; and the conduction trigger block 31 triggers a conduction stroke of conducting the mechanical-conducting component 5, which is different from the conduction stroke of conducting the light-conducting component 6 triggered by the light-blocking protrusion 32. When the conductive core 3 is pressed to move downwards, the conduction trigger block 31 and the light-blocking protrusion 32 move downwards along therewith. Since the conduction stroke of conducting the mechanical-conducting component 5 triggered by the conduction trigger block 31 is different from the conduction stroke of conducting the light-conducting component 6 triggered by the light-blocking protrusion 32, so that the conduction trigger block 31 and the light-blocking protrusion 32 can trigger the conduction of the corresponding conducting component sequentially, achieving the purpose of conducting in sequence.

Specifically, as shown in FIGS. 1, 4 to 9 and 11, the mechanical-conducting component 5 comprises a stationary plate 51 and a movable plate 52, a stationary contact 511 is provided on the stationary plate 51, a movable contact 521 corresponding to the stationary contact 511 is provided on the movable plate 52, and at least one contact protrusion 522 corresponding to the conduction trigger block 31 is formed on the movable plate 52. Meanwhile, an inclined surface 311 is formed on an upper part of a side edge of the conduction trigger block 31. When the conductive core 3 is not pressed and is in a natural state, the contact protrusion 522 of the movable plate 52 is pushed outwards by the conduction trigger block 31, so that the movable plate 52 is elastically deformed, the movable contact 521 on the movable plate 52 is separated from the stationary contact 511 on the stationary plate 51, and the mechanical-conducting component 5 is in an off state; when the conductive core 3 is pressed and moves downwards, the conduction trigger block 31 moves downwards therewith; when the conductive core 3 moves downwards for a certain stroke, the conduction trigger block 31 is separated from the contact protrusion 522 on the movable plate 52 and contacts an inclined surface 311, the outward force applied to the movable plate 52 is reduced, the movable plate 52 is elastically reset, and the movable contact 521 on the movable plate 52 is in contact with the stationary contact 511 on the stationary plate 51. Then, the mechanical-conducting component 5 is in a conductive state.

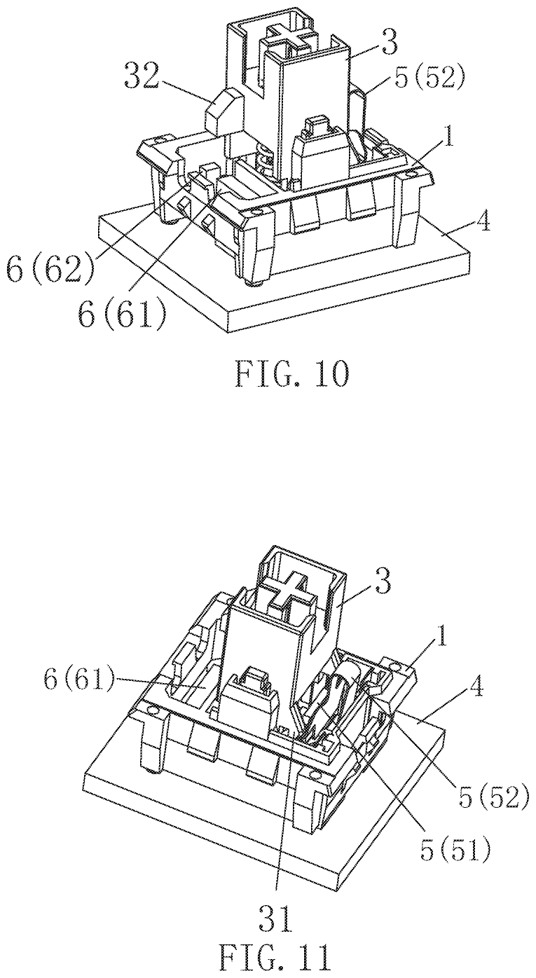

Specifically, as shown in FIGS. 1 and 10, the light-conducting component 6 comprises a light emission element 61 and a light reception element 62. In the case where there is no structural interruption between the light emission element 61 and the light reception element 62, the light emission element 61 emits a light signal, and the light reception element 62 receives a light signal. When the structural interruption occurs between the light emission element 61 and the light reception element 62, the light reception element 52 cannot receive the light signal emitted by the light emission element 51, i.e., a signal in which the optical path is blocked occurs.

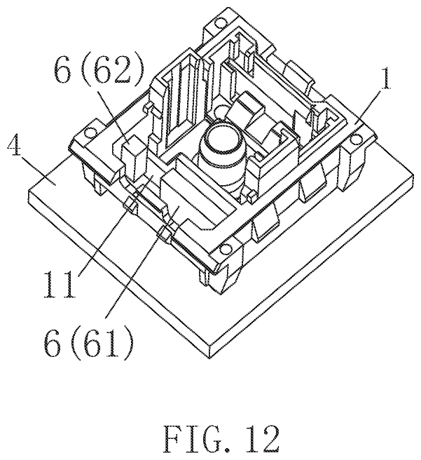

In order to facilitate the upward and downward movement of the light-blocking protrusion 32, an abdicating opening 11 for the light-blocking protrusion 32 to move up and down is formed on the base 1 in the present embodiment, as shown in FIG. 12.

The specific working principle of the light-conducting component 6 is as follows.

In a natural state, the light-blocking protrusion 32 arranged on the conductive core 3 does not reach the light-conducting component 6, and the light reception element 62 in the light-conducting component 6 can normally receive the light signal emitted by the light emission element 61 and can be preset through a circuit on the PCB 4, in which case the light-conducting component 6 is in an off state.

When the conductive core 3 is pressed downwards, the conductive core 3 drives the light-blocking protrusion 32 to move downwards synchronously until the light-blocking protrusion 32 extends between the light emission element 61 and the light reception element 62 to block an optical path between the light emission element 61 and the light reception element 62, so that the light reception element 62 cannot receive a light signal emitted by the light emission element 61, i.e. a signal that the optical path is blocked is generated, and the light-conducting component 6 is set to be conducted.

When the pressing of the conductive core 3 is released, the conductive core 3 moves upwards and resets under the elastic restoring force of a spring 7 to drive the light-blocking protrusion 32 to move upwards. When the light-blocking protrusion 32 leaves from between the light emission element 61 and the light reception element 62, the light reception element 62 receives the light signal emitted by the light emission element 61 again, so that the light-conducting component 6 returns to an off state.

According to the structural characteristics of the mechanical-conducting component 5 and the light-conducting component 6, the conduction strokes of the mechanical-conducting component 5 and the light-conducting component 6 can be set as follows. As shown in FIG. 5, the height d1 of the outer edge of the conduction trigger block 31 close to the mechanical-conducting component 5 is not equal to the distance d2 between the light-blocking protrusion 32 and the light-conducting component 6, thereby realizing different conduction strokes. In the specific structural design, the method can be realized in the following two ways.

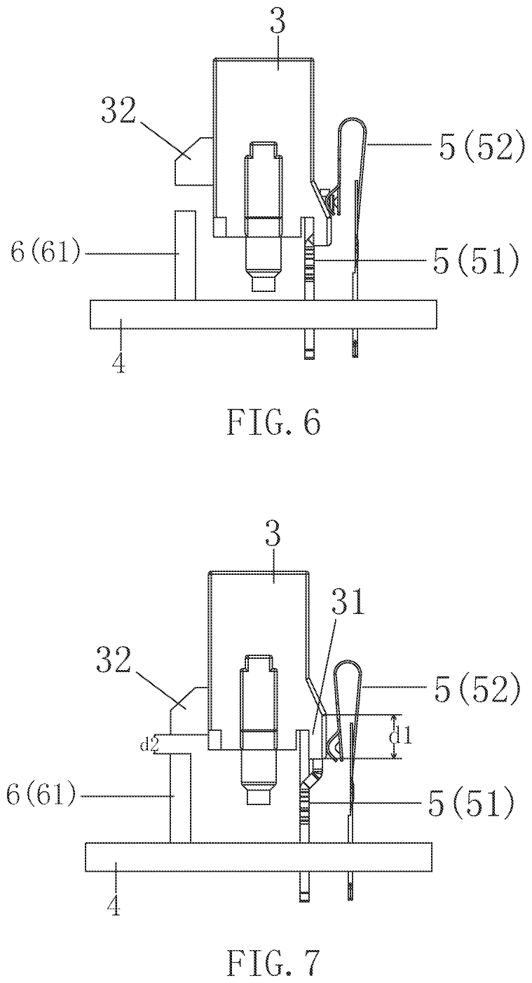

(1) The height d1 of the outer edge of the conduction trigger block 31 close to the mechanical-conducting component 5 is less than the distance d2 between the light-blocking protrusion 32 and the light-conducting component 6, as shown in FIG. 5. When the conductive core 3 is pressed to move downwards, the conduction trigger block 31 and the light-blocking protrusion 32 move downwards synchronously. Since the height d1 of the outer edge of the conduction trigger block 31 close to the mechanical-conducting component 5 is less than the distance d2 between the light-blocking protrusion 32 and the light-conducting component 6, the movable plate 52 of the mechanical-conducting component 5 is elastically reset when the stroke of the conductive core 3 moving downwards exceeds the height d1 and the movable contact 521 on the movable plate 52 is in contact with the stationary contact 511 on the stationary plate 51, and the mechanical-conducting component 5 is then conducted earlier, as shown in FIG. 6. The conductive core 3 continues to move downwards until the light-blocking protrusion 32 enters between the light emission element 61 and the light reception element 62, the optical path of the light-conducting component 6 is blocked, and then the light-conducting component 6 is conducted later. Therefore, the mechanical-conducting component 5 is conducted earlier as compared to the light-conducting component 6, thereby achieving the purpose of conducting in sequence.

When the pressing of the conductive core 3 is released and the conductive core 3 moves upwards and resets, the conduction trigger block 31 and the light-blocking protrusion 32 move upwards synchronously; the light-blocking protrusion 32 firstly leaves the light-conducting component 6, the signal that the light path generated by the light-conducting component 6 is blocked disappears, and the light-conducting component 6 is firstly disconnected; the conductive core 3 continues to move upwards, and the conduction trigger block 31 pushes the movable plate 52 outwards, so that the mechanical-conducting component 5 is disconnected later, i.e. the light-conducting component 6 is disconnected before the mechanical-conducting component 5.

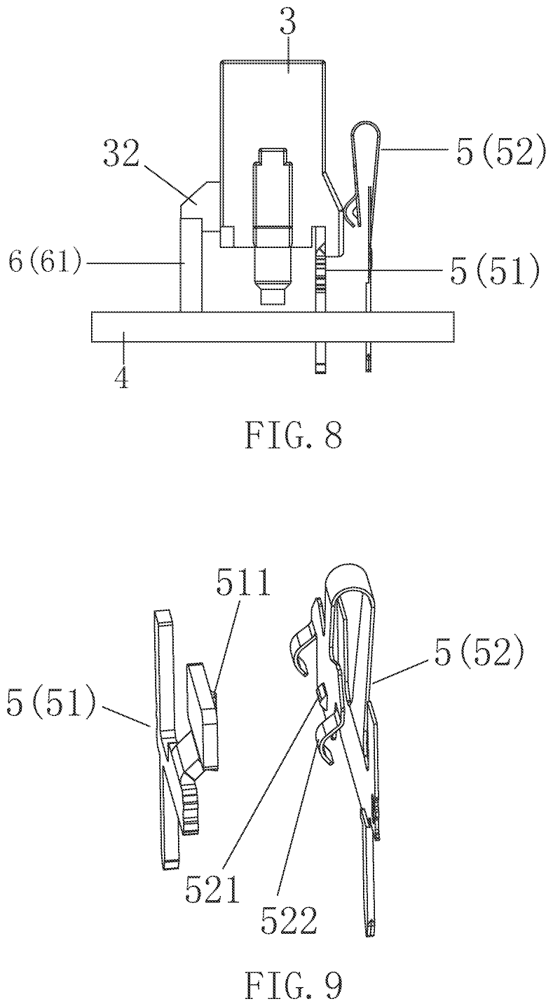

(2) The height d1 of the outer edge of the conduction trigger block 31 close to the mechanical-conducting component 5 is greater than the distance d2 between the light-blocking protrusion 32 and the light-conducting component 6, as shown in FIG. 7. When the conductive core 3 is pressed to move downwards, the conduction trigger block 31 and the light-blocking protrusion 32 move downwards synchronously. Since the height d1 of the outer edge of the conduction trigger block 31 close to the mechanical-conducting component 5 is greater than the distance d2 between the light-blocking protrusion 32 and the light-conducting component 6, the light-blocking protrusion 32 enters between the light emission element 61 and the light reception element 62 when the stroke of the conductive core 3 moving downwards exceeds the distance d2, as shown in FIG. 8, to block the light path of the light-conducting component 6, and the light-conducting component 6 is then conducted earlier. The conductive core 3 continues to move downwards until the stroke moving downwards exceeds the height d1, the movable plate 52 of the mechanical-conducting component 5 is elastically reset, the movable contact 521 on the movable plate 52 is in contact with the stationary contact 511 on the stationary plate 51, and the mechanical-conducting component 5 is conducted later, thereby achieving the purpose of conducting in sequence.

When the pressing of the conductive core 3 is released and the conductive core 3 moves upwards and resets, the conduction trigger block 31 and the light-blocking protrusion 32 move upwards synchronously, and the conduction trigger block 31 pushes the movable plate 52 outwards firstly, so that the mechanical-conducting component 5 is disconnected earlier; the conductive core 3 continues to move upwards, the light-blocking protrusions 32 leave the light-conducting component 6, the signal that the light path generated by the light-conducting component 6 is blocked disappears, and the light-conducting component 6 is then disconnected later. That is, the mechanical-conducting component 5 is disconnected before the light-conducting component 6. In the description above, only the preferred embodiments of the utility model has been described, and the technical scope of the utility model is not limited in any way. Therefore, other structures obtained by adopting the same or similar technical features as those of the above embodiments of the utility model are within the scope of the utility model.

1. A combined dual-conductive key switch comprising a base, a cover arranged above the base and a conductive core, wherein the combined dual-conductive key switch further comprises a mechanical-conducting component and a light-conducting component which are electrically connected to a PCB respectively, wherein a conduction trigger block corresponding to the mechanical-conducting component and a light-blocking protrusion corresponding to the light-conducting component are respectively arranged on the conductive core; and the conduction trigger block triggers a conduction stroke of conducting the mechanical-conducting component, which is different from a conduction stroke of conducting the light-conducting component triggered by the light-blocking protrusion;
wherein the conduction trigger block has a height of an outer edge of the conduction trigger block close to the mechanical-conducting component that is not equal to a distance between the light-blocking protrusion and the light-conducting component.

2. (canceled)

3. The combined dual-conductive key switch according to claim 1, wherein the height of the outer edge of the conduction trigger block close to the mechanical-conducting component is less than the distance between the light-blocking protrusion and the light-conducting component.

4. The combined dual-conductive key switch according to claim 1, wherein the height of the outer edge of the conduction trigger block close to the mechanical-conducting component is greater than the distance between the light-blocking protrusion and the light-conducting component.

5. The combined dual-conductive key switch according to claim 1, wherein an inclined surface is formed on an upper part of a side edge of the conduction trigger block.

6. The combined dual-conductive key switch according to claim 1, wherein the mechanical-conducting component comprises a stationary plate and a movable plate, a stationary contact is provided on the stationary plate, a movable contact corresponding to the stationary contact is provided on the movable plate, and at least one contact protrusion corresponding to the conduction trigger block is formed on the movable plate.

7. The combined dual-conductive key switch according to claim 1, wherein the light-conducting component comprises a light emission element and a light reception element.

8. The combined dual-conductive key switch according to claim 1, wherein an abdicating opening for the light-blocking protrusion to move up and down is formed on the base.
